(19) United States
(12) Patent Application Publication
(10) Pub. No.: US 2021/0375594 A1
(43) Pub. Date: Dec. 2, 2021

(54) APPARATUS AND METHOD FOR TEMPERATURE CONTROL, AND PLASMA EQUIPMENT

(71) Applicant: CHANGXIN MEMORY TECHNOLOGIES, INC., Hefei City (CN)

(72) Inventor: Songyu LI, Hefei (CN)

(21) Appl. No.: 17/399,117

(22) Filed: Aug. 11, 2021

Related U.S. Application Data
(63) Continuation of application No. PCT/CN2021/091842, filed on May 6, 2021.

(30) Foreign Application Priority Data
May 9, 2020 (CN) 202010386829.5

(51) Int. Cl. H01J 37/32

(52) U.S. Cl. CPC H01J 37/32522; H01L 35/02; H01J 37/32954

(57) ABSTRACT

An apparatus and method for temperature control, and plasma equipment. The apparatus for temperature control includes a temperature control component and a control component, the control component is electrically connected to the temperature control component and is configured to obtain an actual temperature of a top electrode in plasma equipment in real time, the temperature control component includes at least one semiconductor cooling device located on a surface of the top electrode, and a plurality of semiconductor cooling fins are configured as a plurality of annular heating blocks, and the control component is configured to control each heating region for cooling or heating.

### CROSS REFERENCE TO RELATED APPLICATIONS

This is a continuation of International Application No. PCT/CN2021/091842, filed on May 6, 2021, and entitled “APPARATUS AND METHOD FOR TEMPERATURE CONTROL, AND PLASMA EQUIPMENT”, which claims priority to Chinese Patent Application No. 202010386829.5, filed on May 9, 2020, and entitled “APPARATUS AND METHOD FOR TEMPERATURE CONTROL, AND PLASMA EQUIPMENT”. The contents of International Application No. PCT/CN2021/091842 and Chinese Patent Application No. 202010386829.5 are hereby incorporated by reference in their entireties.

### TECHNICAL FIELD

The present disclosure relates to the technical field of temperature control, in particular to an apparatus and method for temperature control, and plasma equipment.

### BACKGROUND

Plasma equipment, such as ion etching equipment, uses an electromagnetic field to excite plasmas, and uses high-energy plasmas to physically or chemically react with semiconductors or metals to achieve the purpose of etching.

In order to improve etching instructions, it is necessary to control the temperature of a top electrode. At present, the temperature control is realized generally by heating the top electrode with a resistance wire and cooling the top electrode with a fan. For example, the fan works stably and continuously. Responsive to that the temperature is low, the power of the resistance wire is increased, so the temperature of the top electrode increases; responsive to that the temperature is high, the power of the resistance wire is decreased, so the temperature of the top electrode decreases.

However, in the case of sudden temperature changes, the temperature control effect achieved by the above method is not good and the specific problems are as follows.

Responsive to that the ion bombardment causes the temperature of the top electrode to increase during the etching process, it is difficult for the existing temperature control method to quickly cool the top electrode, which often leads to the temperature of the top electrode to be higher in the first few steps of a device being etched firstly.

During the etching process, responsive to that the power is changed, the temperature of the top electrode will change accordingly, so it is difficult for the existing temperature control method to stabilize the temperature quickly.

### SUMMARY

One aspect of the present disclosure provides an apparatus for temperature control, including: a temperature control component; and a control component, electrically connected to the temperature control component and configured to obtain an actual temperature of a top electrode in plasma equipment in real time, and control the temperature control component to heat or cool the top electrode according to a preset temperature and the actual temperature.

Another aspect of the present disclosure provides plasma equipment, including the above apparatus for temperature control, the apparatus for temperature control being located above the top electrode of the plasma equipment.

Yet another aspect of the present disclosure provides a method for temperature control, applied to the apparatus for temperature control, the method includes: obtaining the actual temperature of the top electrode in the plasma equipment in real time; and controlling the temperature control component to heat or cool the top electrode according to the preset temperature and the actual temperature.

Details of one or more embodiments of the present disclosure will be set forth in the following drawings and description. Other features, objectives and advantages of the present disclosure will become apparent from the description, the drawings and the claims.

### BRIEF DESCRIPTION OF THE DRAWINGS

In order to more clearly describe the technical solution of the embodiments of the present disclosure, one or more drawings may be referred to, but the additional details or examples used to describe the drawings shall not be considered as limiting the scope of any one of the present disclosure, the currently described embodiments or preferred manners of the present disclosure.

FIG. 1 illustrates an electrical structural schematic diagram of an apparatus for temperature control provided by the embodiments of the present disclosure.

FIG. 2 illustrates a schematic diagram of an operating principle of a semiconductor cooling device provided by the embodiments of the present disclosure.

FIG. 3 illustrates an electrical structural schematic diagram of semiconductor cooling fins provided by the embodiments of the present disclosure.

FIG. 4 illustrates a structural schematic diagram of semiconductor cooling fins provided by the embodiments of the present disclosure.

FIG. 5 illustrates a schematic diagram of an arrangement of a plurality of semiconductor cooling fins provided by the embodiments of the present disclosure.

FIG. 6 illustrates a schematic diagram of another arrangement of a plurality of semiconductor cooling fins provided by the embodiments of the present disclosure.

FIG. 7 illustrates a structural schematic diagram of a current control circuit provided by the embodiments of the present disclosure.

FIG. 8 illustrates a flowchart of a method for temperature control applied to an apparatus for temperature control and provided by the embodiments of the present disclosure.

### DETAILED DESCRIPTION

In order to facilitate the understanding of the present disclosure, the present disclosure will be more comprehensively described below with reference to the relevant drawings. Embodiments of the present disclosure are illustrated in the drawings. However, the present disclosure may be implemented in many different modes and is not limited to the embodiments described herein. On the contrary, the purpose of providing these embodiments is to make the disclosure of the present disclosure more thorough and comprehensive.

Unless otherwise defined, all technical and scientific terms used herein have the same meanings as those commonly understood by those skilled in the art of the present disclosure. The terms used in the description of the present disclosure are only for the purpose of describing specific embodiments, and are not intended to limit the present disclosure.

It should be understood that the spatial relationship terms such as “under”, “below”, “lower”, “beneath”, “above” and “upper” can be used here to describe the relationship between one element or feature and other elements or features illustrated in the drawing. It should be understood that in addition to the orientations illustrated in the drawings, the spatial relationship terms further include different orientations of the devices in use and operation. For example, if the device in the drawing is turned over, the element or feature described as “below other elements” or “below it” or “beneath it” will be oriented “above” the other elements or features. Therefore, the exemplary terms “under” and “below” may include both upward and downward orientations. In addition, the device may also include additional orientations (e.g., 90 degrees of rotation or other orientations), and the spatial descriptions used herein are interpreted accordingly.

When used here, singular forms of “a”, “one” and “said/the” may also include plural forms, unless the context clearly indicates otherwise. It should also be understood that the terms “including/comprising” or “having” specify the existence of the stated feature, whole, step, operation, component, part or combinations thereof, but do not exclude the possibility of the existence or addition of one or more other features, wholes, steps, operations, components, parts or combinations thereof. Meanwhile, in this description, the term “and/or” includes any and all combinations of the relevant listed items.

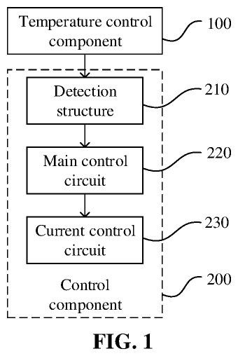

Please referring to FIG. 1, the embodiment of the present provides an apparatus for temperature control, which includes a temperature control component 100 and a control component 200. The control component 200 is electrically connected to the temperature control component 100 and configured to obtain an actual temperature of a top electrode in plasma equipment in real time, and control the temperature control component 100 to heat or cool the top electrode according to a preset temperature and the actual temperature.

It can be understood that a coil in a top electrode of ion etching equipment generally generates an electromagnetic field under the action of a Radio Frequency (RF) power supply and generates plasmas in a vacuum cavity. Under the action of the RF power supply, a bottom electrode forms a bias electric field, which controls the movement speed and direction of ions bombarding a wafer. It is inevitable that some high-energy particles will bombard the top electrode under the action of the electromagnetic field, thus heating the top electrode. Since the temperature of the top electrode is uneven and continuously changes with time, particle scales and the like will be formed on the lower surface, which are easy to affect the etching process. Therefore, it is necessary to control the top electrode at a preset temperature to improve the etching quality. In this embodiment, the actual temperature of the top electrode in the plasma equipment is obtained in real time, and the temperature control component 100 is controlled to heat or cool the top electrode according to the preset temperature and the actual temperature, thus realizing a quick response in case of abnormal temperature, making the actual temperature approach the preset temperature, and helping improve the temperature control effect.

In one embodiment, responsive to that the actual temperature is higher than the preset temperature, the control component 200 is configured to control the temperature control component 100 to cool the top electrode.

Responsive to that the actual temperature is lower than the preset temperature and the difference between the actual temperature and the preset temperature is more than a temperature difference threshold, the control component 200 is configured to control the temperature control component 100 to heat the top electrode.

Responsive to that the actual temperature is equal to the preset temperature, the control component 200 is configured to control the temperature control component 100 to stop working.

In this embodiment, the control component 200 compares the actual temperature with the preset temperature, and performs a corresponding operation according to the comparison result, thus realizing a quick response in case of abnormal temperature and making the actual temperature approach the preset temperature. For example, assuming that the preset temperature T₀ is 80° C., responsive to that the actual temperature T is higher than 80° C., the temperature control component 100 is used to cool the top electrode; responsive to that the actual temperature T is lower than 80° C., the temperature control component 100 is used to heat the top electrode; and, responsive to that the actual temperature T is equal to 80° C., it indicates that the temperature of the top electrode is just suitable at this time, and the temperature control component 100 can be controlled to stop working by means of cutting off power or enabling a sleep mode.

In order to avoid frequently changing the state of the temperature control component 100, in other embodiments, responsive to that the actual temperature is higher than the preset temperature and the difference between the actual temperature and the preset temperature is more than the temperature difference threshold, the control component 200 is configured to control the temperature control component 100 to cool the top electrode; and when the actual temperature is lower than the preset temperature and the difference between the actual temperature and the preset temperature is more than the temperature difference threshold, the control component 200 is configured to control the temperature control component 100 to heat the top electrode.

In this embodiment, the temperature difference threshold Δt is an absolute difference between the actual temperature and the preset temperature, i.e., Δt=|T−T₀|. It is assumed that the preset temperature T₀ is 80° C. and the temperature difference threshold Δt is 1° C. It can be understood that, by limiting the operating state of the temperature control component 100 to be changed responsive to that the difference between the actual temperature and the preset temperature is more than the temperature difference threshold, it can avoid changing the state responsive to that the actual temperature is slightly higher or lower than the preset temperature. In addition, when the temperature difference threshold Δt is within 1° C., the etching process will not be adversely affected. It should be noted that the specific value of the temperature difference threshold is not limited in this embodiment, and the temperature difference threshold may be set according to the actual requirements of the etching process in the specific process.

In one embodiment, the temperature control component 100 includes at least one semiconductor cooling device located on a surface of the top electrode.

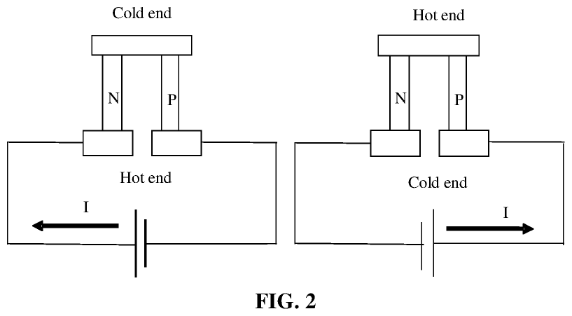

Please refer to FIG. 2. When direct current passes through the semiconductor cooling device, one end of the semiconductor cooling device absorbs heat and the other end opposite to it releases heat. In addition, a hot end and a cold end of the semiconductor cooling device are interchangeable, depending on the direction of the current. Specifically, responsive to that the actual temperature is lower than the preset temperature, clockwise current can be provided to the semiconductor cooling device, so that the end of the semiconductor cooling device close to the top electrode is the hot end to heat the top electrode. Correspondingly, responsive to that the actual temperature is higher than the preset temperature, anticlockwise current can be provided to the semiconductor cooling device, so that the end of the semiconductor cooling device close to the top electrode is the cold end to cool the top electrode. Since the semiconductor cooling device is a current transducer type sheet, the thermal inertia is very small and the cooling and heating speed is very fast. By the control of input current, high-precision and fast temperature control can be realized. In addition, with the means of temperature detection and control, it is very easy to realize remote control, program control and computer control, which facilitates the formation of an automatic control system.

In one embodiment, the semiconductor cooling device includes at least one semiconductor cooling fin. In this embodiment, the semiconductor cooling device includes a plurality of semiconductor cooling fins, and each semiconductor cooling fin is driven by the control component 200, thus further improving the temperature control precision.

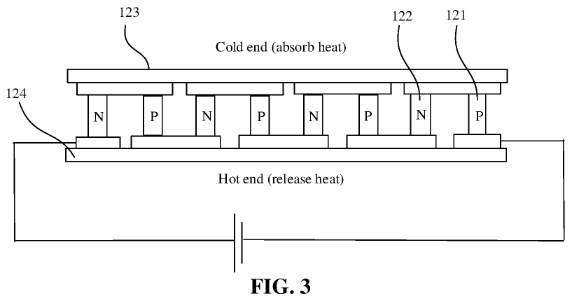

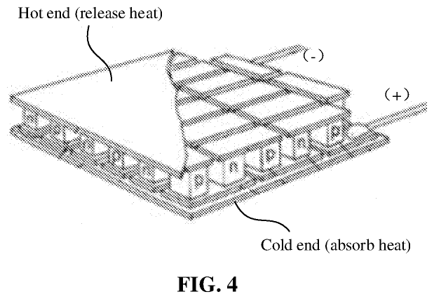

With reference to FIG. 3 and FIG. 4. The semiconductor cooling fin includes at least one separate cooling element. The separate cooling element includes a P-type semiconductor 121, an N-type semiconductor 122, a heat conducting graphite sheet 123 and a ceramic sheet 124. The power of a pair of the separate cooling elements of the semiconductor cooling fin is very small. However, when combined to form the semiconductor cooling fins and the same type of semiconductor cooling fins are connected in parallel or series to form a cooling system, the power can be very large.

The ceramic sheet 124 is located on the same side of the P-type semiconductor 121 and the N-type semiconductor 122. The heat conducting graphite sheet 123 is located on the side of the P-type semiconductor 121 or the N-type semiconductor 122 far away from the ceramic sheet 124. The P-type semiconductor 121, the N-type semiconductor 122, the heat conducting graphite sheet 123 and the ceramic sheet 124 are closely bonded. In the specific process, the materials of the P-type semiconductor 121 and the N-type semiconductor 122 may be CoSb₃ skutterudite thermoelectric materials, Half-Heusler thermoelectric materials, doped Si—Ge alloys, Zintl phase thermoelectric materials and other thermoelectric materials, which filled with one or more of doped pseudo binary bismuth telluride Bi₂Te₃ and its solid solution, pseudo ternary bismuth telluride and its solid solution, doped lead telluride PbTe and its solid solution (such as PbTe—SnTe, PbTe—SnTe—MnTe), and germanium telluride GeTe and its solid solution (such as GeTe—PbTe, GeTe—AgSbTe₂).

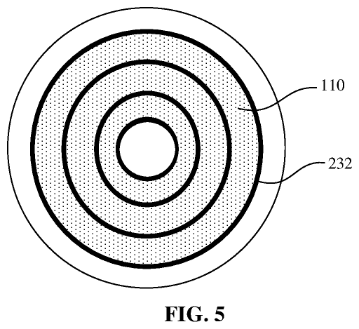

Please refer to FIG. 5. In one embodiment, the temperature control component includes a plurality of semiconductor cooling fins, the plurality of semiconductor cooling fins form a plurality of annular heating blocks 110 arranged concentrically, of which a number of semiconductor cooling fins located in a same annular heating block are in parallel connection, series connection or series and parallel connection. It can be understood that the temperature uniformity of the top electrode can be improved by enabling the plurality of semiconductor cooling fins to form regions of the top electrode corresponding to annular heating blocks 110 arranged concentrically.

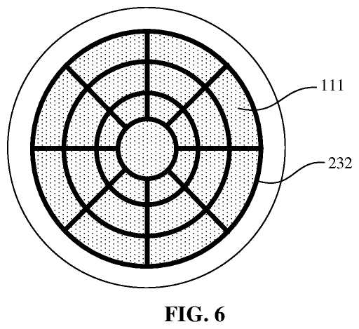

Please refer to FIG. 6. In one embodiment, the annular heating blocks are divided into a plurality of heating regions 111, and the control component 200 is configured to control each heating region 111 for cooling or heating.

It can be understood that the temperatures of different positions in the region of the top electrode corresponding to a same annular heating block may be different. Therefore, the precision of temperature control is further improved by dividing the annular heating block into the plurality of heating regions 111 and controlling each heating region 111 for cooling or heating through the control component 200.

In one embodiment, a ratio of a total surface area of a side of the top electrode facing the temperature control component 100 to a total surface area of the top electrode covered by the plurality of the semiconductor cooling fins is in a range of 1 to 5.

Since the cooling and heating effect of the semiconductor cooling fins is good, the semiconductor cooling fins may be arranged to fully cover the surface of the top electrode, or the semiconductor cooling fins may be arranged at even spacing without affecting the temperature control effect, so as to reduce the manufacturing cost. In this embodiment, the ratio of the total surface area of the side of the top electrode facing the temperature control component 100 to the total surface area of the top electrode covered by the plurality of semiconductor cooling fins is in a range of 2 to 3, thus reducing the manufacturing cost on the premise of ensuring the temperature control effect.

In one embodiment, the control component 200 includes a detection structure 210, a main control circuit 220 and a current control circuit 230.

The detection structure 210 is configured to obtain the actual temperature of the top electrode in real time. Generally, the detection structure 210 includes a plurality of temperature measuring elements, such as thermocouples, thermal resistors or thermistors. In this embodiment, if the temperature control component includes a plurality of heating regions, the detection structure 210 will detect the actual temperature of each heating region in real time.

The main control circuit 220 is electrically connected to the detection structure 210 and configured to compare the preset temperature with the actual temperature, generate a first control signal responsive to that the actual temperature is higher than the preset temperature, generate a second control signal responsive to that the actual temperature is equal to the preset temperature, and generate a third control signal responsive to that the actual temperature is lower than the preset temperature.

The current control circuit 230 is electrically connected to the main control circuit 220 and the semiconductor cooling device respectively, and configured to provide an operating current in a first direction to the semiconductor cooling device according to the first control signal, stop supplying power to the semiconductor cooling device according to the second control signal, and provide an operating current in a second direction to the semiconductor cooling device according to the third control signal. The first direction and the second direction are opposite.

In this embodiment, it is assumed that the preset temperature is 80° C., the value of the temperature difference threshold Δt is 1, the operating current in the first direction is the current in an anticlockwise direction as illustrated in FIG. 2, and the operating current in the second direction is the current in a clockwise direction as illustrated in FIG. 2. In order to avoid frequently switching the circuit, responsive to that the difference between the actual temperature T and the preset temperature T₀ is equal to or less than the temperature difference threshold Δt, i.e., 1, the actual temperature T is approximately considered to be the same as the preset temperature T₀. In the specific operating process, responsive to that the main control circuit 220 determines that the difference between the actual temperature T and the preset temperature T₀ is equal to or less than the temperature difference threshold Δt, i.e., 1, a second control signal is generated and transmitted to the current control circuit 230, and the current control circuit 230 stops supplying power to the semiconductor cooling device to maintain the current temperature of the electrode. Responsive to that the actual temperature T is higher than the preset temperature T₀, and the difference between the actual temperature T and the preset temperature T₀ is more than the temperature difference threshold Δt, that is, responsive to that the actual temperature exceeds 81° C., it indicates that the top electrode is overheated at this time and needs to be cooled, at this time the main control circuit generates a first control signal and transmits it to the current control circuit 230, and the current control circuit 230 provides operating current in the second direction (i.e., anticlockwise direction) to the semiconductor cooling fins, making the end of the semiconductor cooling device close to the top electrode be a cold end to cool the top electrode. Responsive to that the actual temperature T is lower than the preset temperature T₀, and the difference between the actual temperature T and the preset temperature T₀ is more than the temperature difference threshold Δt, that is, when the actual temperature is lower than 79° C., it indicates that the top electrode is supercooled at this time and needs to be heated, at this time the main control circuit generates a third control signal and transmits it to the current control circuit 230, the current control circuit 230 provides operating current in the first direction (i.e., clockwise direction) to the semiconductor cooling fins, making the end of the semiconductor cooling device close to the top electrode be a hot end to heat the top electrode, so as to realize heating and cooling of the top electrode through one temperature control device.

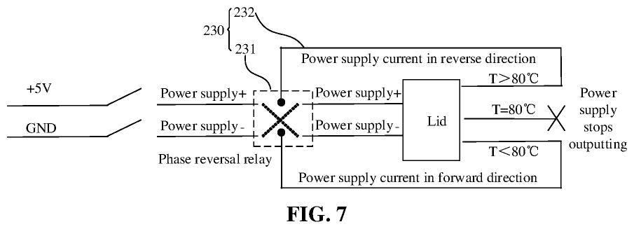

Please refer to FIG. 7. In one embodiment, the current control circuit 230 includes a plurality of phase reversal relays 231 and a plurality of conductive wire groups 232, each of the phase reversal relays 231 corresponds to a respective one of the conductive wire groups 232 and a respective one of the heating regions 111.

A control end of the phase reversal relay is electrically connected to the main control circuit 220, two moving contacts of the phase reversal relay are electrically connected to a positive output end and a negative output end of a power supply respectively, two stationary contacts of the phase reversal relay are electrically connected to a positive input end and a negative input end of the corresponding conductive wire group 232 respectively, and provide an operating current to the semiconductor cooling fin in the corresponding heating region through the conductive wire group 232.

It can be understood that, in order to improve the temperature uniformity of the top electrode, the semiconductor cooling fins in the semiconductor refrigeration device are divided into a plurality of heating regions 111 as required, and the control component 200 is configured to control each heating region 111 for cooling or heating. In order to control each heating region 111 separately, it is necessary to configure a phase reversal relay 231 and a conductive wire group 232 for each heating region 111. The phase reversal relay 231 changes the direction of the operating current according to the control of the main control circuit, and provides the operating current to the conductive wire group 232, which is then provided to the semiconductor cooling fins in the heating region through the conductive wire group 232. Since the operating mode of the semiconductor cooling fin in each heating region 111 is the same and of which a number of the semiconductor cooling fins located in a same annular heating region 110 are in parallel connection, series connection or series and parallel connection, the operating current can be provided to the semiconductor cooling fins in a same heating region 111 through one conductive wire group 232.

In one embodiment, the conductive wire group 232 is located between adjacent ones of the heating regions 111. It can be understood that the space utilization ratio can be improved by arranging the conductive wire group 232 in the region between the adjacent ones of the heating regions 111.

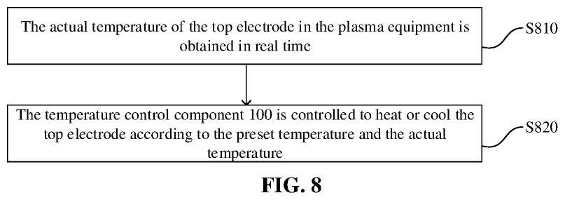

Please refer to FIG. 8. Based on the same invention concept, aiming at the apparatus for temperature control provided by any embodiment, the embodiment of the present disclosure further provides a method for temperature control applied to the apparatus for temperature control, which includes the following operations.

In S810, the actual temperature of the top electrode in the plasma equipment is obtained in real time.

In S820, the temperature control component 100 is controlled to heat or cool the top electrode according to the preset temperature and the actual temperature.

In this embodiment, the actual temperature of the top electrode in the plasma equipment is obtained in real time, and the temperature control component 100 is controlled to heat or cool the top electrode according to the preset temperature and the actual temperature, thus realizing a quick response in case of abnormal temperature, and helping improve the temperature control effect.

In one embodiment, the temperature control component 100 includes at least one semiconductor cooling device, and the operation of controlling the temperature control component to heat or cool the top electrode according to the preset temperature and the actual temperature includes:

generating a first control signal responsive to that the actual temperature is higher than the preset temperature;

providing an operating current in a first direction to the semiconductor cooling device according to the first control signal, and cooling the top electrode by the semiconductor cooling device;

generating a second control signal responsive to that the actual temperature is equal to the preset temperature;

stopping supplying power to the semiconductor cooling device according to the second control signal;

generating a third control signal responsive to that the actual temperature is lower than the preset temperature; and

providing an operating current in a second direction to the semiconductor cooling device according to the third control signal, and heating the top electrode by the semiconductor cooling device. The first direction and the second direction are opposite.

In this embodiment, the control component 200 compares the actual temperature with the preset temperature, and performs a corresponding operation according to the comparison result, thus realizing a quick response in case of abnormal temperature and making the actual temperature approach the preset temperature. For example, assuming that the preset temperature T₀ is 80° C., responsive to that the actual temperature T is higher than 80° C., the temperature control component 100 is used to cool the top electrode; responsive to that the actual temperature T is lower than 80° C., the temperature control component 100 is used to heat the top electrode; and, responsive to that the actual temperature T is equal to 80° C., it indicates that the temperature of the top electrode is just suitable at this time, and the temperature control component 100 can be controlled to stop working by means of cutting off power or enabling a sleep mode.

In addition, when direct current passes through the semiconductor cooling device, one end of the semiconductor cooling device absorbs heat and the other end opposite to it releases heat. In addition, a hot end and a cold end of the semiconductor cooling device are interchangeable, depending on the direction of the current. Specifically, responsive to that the actual temperature is lower than the preset temperature, clockwise current can be provided to the semiconductor cooling device, so that the end of the semiconductor cooling device close to the top electrode is the hot end to heat the top electrode. Correspondingly, responsive to that the actual temperature is higher than the preset temperature, anticlockwise current can be provided to the semiconductor cooling device, so that the end of the semiconductor cooling device close to the top electrode is the cold end to cool the top electrode. Since the semiconductor cooling device is a current transducer type sheet, the thermal inertia is very small and the cooling and heating speed is very fast. By the control of input current, high-precision and fast temperature control can be realized. In addition, with the means of temperature detection and control, it is very easy to realize remote control, program control and computer control, which facilitates the formation of an automatic control system.

Based on the same invention concept, the embodiment of the present disclosure further provides plasma equipment, which includes the apparatus for temperature control according to any one of the embodiments. The apparatus for temperature control is located above a top electrode of the plasma equipment.

In this description, the description of reference terms “one embodiment”, “other embodiments” and the like means that a specific feature, structure, material or feature described in connection with the embodiment or example is included in at least one embodiment or example of the present disclosure. In this description, the schematic description of the terms does not necessarily refer to the same embodiment or example.

The technical features of the embodiments may be freely combined. In order to make the description concise, all possible combinations of the technical features of the embodiments are not described. However, as long as there is no contradiction in the combinations of these technical features, they should be considered as included in the scope of the description.

The embodiments only express several implementations of the present disclosure, and the description thereof is more specific and detailed, but it cannot be understood as a limitation to the scope of the present disclosure. It should be pointed out that those skilled in the art may further make various variations and improvements without departing from the invention concept, which should be included in the scope of protection of the present disclosure. Therefore, the scope of protection of the present patent should be subject to the attached claims.

1. An apparatus for temperature control, comprising:
a temperature control component; and
a control component, electrically connected to the temperature control component and configured to obtain an actual temperature of a top electrode in plasma equipment in real time, and control the temperature control component to heat or cool the top electrode according to a preset temperature and the actual temperature.

2. The apparatus for temperature control of claim 1, wherein responsive to that the actual temperature is higher than the preset temperature, the control component is configured to control the temperature control component to cool the top electrode;
responsive to that the actual temperature is lower than the preset temperature, the control component is configured to control the temperature control component to heat the top electrode; or
responsive to that the actual temperature is equal to the preset temperature, the control component is configured to control the temperature control component to stop working.

3. The apparatus for temperature control of claim 1, wherein the temperature control component comprises at least one semiconductor cooling device located on a surface of the top electrode.

4. The apparatus for temperature control of claim 3, wherein the semiconductor cooling device comprises at least one semiconductor cooling fin.

5. The apparatus for temperature control of claim 4, wherein the temperature control component comprises a plurality of semiconductor cooling fins, the plurality of semiconductor cooling fins form a plurality of annular heating blocks arranged concentrically, of which a number of semiconductor cooling fins located in a same annular heating block are in parallel connection, series connection or series and parallel connection.

6. The apparatus for temperature control of claim 5, wherein the annular heating block is divided into a plurality of heating regions, and the control component is configured to control each heating region for cooling or heating.

7. The apparatus for temperature control of claim 4, wherein a ratio of a total surface area of a side of the top electrode facing the temperature control component to a total surface area of the top electrode covered by the plurality of the semiconductor cooling fins is in a range of 1 to 5.

8. The apparatus for temperature control of claim 6, wherein the control component comprises:
a detection structure, configured to obtain the actual temperature of the top electrode in real time;
a main control circuit, electrically connected to the detection structure and configured to compare the preset temperature with the actual temperature, generate a first control signal responsive to that the actual temperature is higher than the preset temperature, generate a second control signal responsive to that the actual temperature is equal to the preset temperature, and generate a third control signal responsive to that the actual temperature is lower than the preset temperature; and
a current control circuit, electrically connected to the main control circuit and the semiconductor cooling device respectively, configured to provide an operating current in a first direction to the semiconductor cooling device according to the first control signal, stop supplying power to the semiconductor cooling device according to the second control signal, and provide an operating current in a second direction to the semiconductor cooling device according to the third control signal, wherein the first direction and the second direction are opposite.

9. The apparatus for temperature control of claim 8, wherein the current control circuit comprises a plurality of phase reversal relays and a plurality of conductive wire groups, each of the phase reversal relays corresponds to a respective one of the conductive wire groups and a respective one of the heating regions; and
a control end of the phase reversal relay is electrically connected to the main control circuit, two moving contacts of the phase reversal relay are electrically connected to a positive output end and a negative output end of a power supply respectively, two stationary contacts of the phase reversal relay are electrically connected to a positive input end and a negative input end of the corresponding conductive wire group respectively, and provide an operating current to the semiconductor cooling fin in the corresponding heating region through the conductive wire group.

10. The apparatus for temperature control of claim 9, wherein the conductive wire group is located between adjacent ones of the heating regions.

11. Plasma equipment, comprising:
an apparatus for temperature control, comprising:
a temperature control component; and
a control component, electrically connected to the temperature control component and configured to obtain an actual temperature of a top electrode in the plasma equipment in real time, and control the temperature control component to heat or cool the top electrode according to a preset temperature and the actual temperature,
wherein the apparatus for temperature control is located above the top electrode of the plasma equipment.

12. The plasma equipment of claim 11, wherein responsive to that the actual temperature is higher than the preset temperature, the control component is configured to control the temperature control component to cool the top electrode;
responsive to that the actual temperature is lower than the preset temperature, the control component is configured to control the temperature control component to heat the top electrode; or
responsive to that the actual temperature is equal to the preset temperature, the control component is configured to control the temperature control component to stop working.

13. The plasma equipment of claim 11, wherein the temperature control component comprises at least one semiconductor cooling device located on a surface of the top electrode.

14. The plasma equipment of claim 13, wherein the semiconductor cooling device comprises at least one semiconductor cooling fin.

15. The plasma equipment of claim 14, wherein the temperature control component comprises a plurality of semiconductor cooling fins, the plurality of semiconductor cooling fins form a plurality of annular heating blocks arranged concentrically, of which a number of semiconductor cooling fins located in a same annular heating block are in parallel connection, series connection or series and parallel connection.

16. The plasma equipment of claim 15, wherein the annular heating block is divided into a plurality of heating regions, and the control component is configured to control each heating region for cooling or heating.

17. The plasma equipment of claim 14, wherein a ratio of a total surface area of a side of the top electrode facing the temperature control component to a total surface area of the top electrode covered by the plurality of the semiconductor cooling fins is in a range of 1 to 5.

18. The plasma equipment of claim 16, wherein the control component comprises:
a detection structure, configured to obtain the actual temperature of the top electrode in real time;
a main control circuit, electrically connected to the detection structure and configured to compare the preset temperature with the actual temperature, generate a first control signal responsive to that the actual temperature is higher than the preset temperature, generate a second control signal responsive to that the actual temperature is equal to the preset temperature, and generate a third control signal responsive to that the actual temperature is lower than the preset temperature; and
a current control circuit, electrically connected to the main control circuit and the semiconductor cooling device respectively, configured to provide an operating current in a first direction to the semiconductor cooling device according to the first control signal, stop supplying power to the semiconductor cooling device according to the second control signal, and provide an operating current in a second direction to the semiconductor cooling device according to the third control signal, wherein the first direction and the second direction are opposite.

19. A method for temperature control, applied to an apparatus for temperature control, the method comprising:
obtaining an actual temperature of a top electrode in plasma equipment in real time; and
controlling a temperature control component in the apparatus for temperature control to heat or cool the top electrode according to a preset temperature and an actual temperature.

20. The method of claim 19, wherein the controlling the temperature control component to heat or cool the top electrode according to the preset temperature and the actual temperature comprises:
generating a first control signal responsive to that the actual temperature is higher than the preset temperature;
providing an operating current in a first direction to a semiconductor cooling device in the temperature control component according to the first control signal, and cooling the top electrode by the semiconductor cooling device;
generating a second control signal responsive to that the actual temperature is equal to the preset temperature;
stopping supplying power to the semiconductor cooling device according to the second control signal;
generating a third control signal responsive to that the actual temperature is lower than the preset temperature; and
providing an operating current in a second direction to the semiconductor cooling device according to the third control signal, and heating the top electrode by the semiconductor cooling device, wherein the first direction and the second direction are opposite.
